(19) United States
(12) Patent Application Publication
(10) Pub. No.: US 2012/0020033 A1
(43) Pub. Date: Jan. 26, 2012

(54) Skin-Safe Conductive Ink and Method for Application on the Body

(75) Inventors: Rebecca L. Pilditch, Cambridgeshire (GB); Isabel Lizardi, Wallingford, CT (US); Bibiana C. Nelson, London (GB); Matt M. Johnson, Aspen, CO (US)

(73) Assignee: BARE CONDUCTIVE LTD, London (UK)

(21) Appl. No.: 13/147,690

(22) PCT Filed: Feb. 4, 2010
(86) PCT No.: PCT/GB2010/000211

§ 371 Date: Oct. 13, 2011

(30) Foreign Application Priority Data
Feb. 4, 2009 (GB) 0901721.1

(51) Int. Cl. H05K 1/09; C09D 11/00

(52) U.S. Cl. 361/748; 106/31.03

(57) ABSTRACT

An ink comprising a particulate conductive material, a binder and a humectant, the conductive material being present in sufficient amount that the ink, once dry, is electrically conductive, may be applied, for example, to the human or animal body and enables such a body to function as part of an electrical circuit.

The present invention relates to an ink that may safely be applied to the human or animal skin, to uses of this ink, including such application, and to methods for such application.

In an era when life is increasingly dominated by gadgets and machines, there is a drive towards the miniaturisation of electronics for the purpose of portability on and around the body. With modern technology there is no reason why the functionality of a mobile phone, for example, could not now be included on the surface of the human or animal body. Current trends towards a post-desktop model of human-computer interaction suggest that information processing will become more integrated into everyday objects and activities. The concept of printing electronics onto the body or using the skin as a substrate for electrical devices fits with this model. It would allow an individual to engage with computational devices and systems via gesture and intuition. It would also allow the creation of new methods of human-computer interaction as well as custom, temporary electronics.

Conductive materials are used to attach wires leading to measuring instruments, e.g. an electrocardiograph, to the skin. However, such materials are putty-like and do not function as an ink.

There are several patents that describe technologies using the body to transfer information. For example, a body antenna system developed at Queen's University Belfast, Northern Ireland. “ANTENNAS” (WO2009010724 (A1), Appendix II) comprises a type of antenna that can be used on the human body. This technology uses the boundary layer of air around the body to transmit signals between portable devices. By using a special low profile antenna, a “creeping wave” is generated. This wave is more efficient and thus requires less power than a comparable technology (such as Bluetooth) would.

An invention called “Firmo,” developed by Nippon Telegraph & Telephone Corp. (NTT), uses a small device placed in the pocket to transfer specific signals across the surface of the body. There are a number of patents that refer to this technology, for example JP10229357(A), “Information Transmitter Via Human Body”, and U.S. Pat. No. 6,223,018 (B1), “Intra-Body Information Transfer Device”. This technology allows for information transfer between person and machine by touching a specific surface. The device in the user's pocket creates a “weak AC electric field” around the person's body, pulsing with a specific signal. When the user makes contact with the receiving device this pulsing is decoded into the information contained within the transmitting device in the user's pocket. The patent lists potential applications as “security and convenience.” For example, this device would allow people to open secured doors just by touching the handle if they had the appropriate key card in their pocket.

Conventional conductive inks are currently used in the electronics industry for printing circuit boards or repairing circuit breaks. They are constructed from copper, silver, conductive polymer, graphite or carbon and are applied using methods such as inkjet printing or by pen. They are designed for high conductivity and generally contain toxic metals and solvents, unsafe for application to the skin and dangerous if inhaled. These inks are not designed to be applied to materials such as the skin, which flex and sweat. In addition, conventional conductive inks are difficult to recycle.

The present invention differs from these in that it applies a flexible non-toxic conductive ink to the skin surface.

Thus, the present invention consists in an ink suitable for application to the human or animal body and comprising a particulate conductive material, a binder and a humectant, the conductive material being present in sufficient amount that the ink, once dry, is electrically conductive.

The invention further consists in an electrical circuit comprising an electrical power source, and a device utilising electrical power, said source and said device being connected by electrically conductive means, at least part of said means comprising an ink applied to the human or animal body and comprising a particulate conductive material, a binder and a humectant.

It will be appreciated that the whole or part of the circuit may be on the human or animal body. Where only part of the circuit is on the body, the circuit may be broken by the body or part of the body moving away from the remainder of the circuit, thus forming a switch. The circuit may also be manipulated (in an analogue fashion, as opposed to the binary action of a switch) by stretching the ink (by stretching the underlying skin that the ink has been applied to), thus changing the resistance value of the ink, which changes when it is attenuated.

Connections between the ink and electronic devices may be made in two ways: through devices carried on the body or through devices placed off the body. If the electronics are worn on the body (e.g. a mobile phone) the connection to the ink may be made through electrodes connected to the device placed on the skin in direct contact with the ink. If the electronics exist off body (e.g. electrodes placed on the built environment or other objects) then the user need only make contact between two or more points to complete a circuit. Whether the electronics exist on body or off, the aim of the technology is to allow a user to interface with electronics through simple movement and touch.

There are three crucial components of the composition of the present invention: a particulate conductive material; a binder; and a humectant.

The particulate conductive material must be capable of forming a conductive layer when applied from the composition. Examples of such materials include: metals, such as powdered or flake silver, gold or copper; or conductive non-metals, such as carbon. Of these, the various electrically conductive forms of carbon are preferred, for example graphite, carbon black, activated carbon powder, powdered activated carbon, carbon nanotubes or powdered charcoal. Because, unlike the metallic material, it is non-toxic, carbon powder or flakes are preferred.

In principle, it is desirous to include as much of the conductive material as possible, in order to maximise the conductivity of the applied composition. However, the composition must also contain at least a humectant and a binder. Accordingly, we prefer to include at least 30% by weight of the conductive material, based on the wet weight of the composition. More preferably, the composition contains at least 35%, still more preferably from 35 to 70% by weight of the conductive composition. Most preferably, the composition contains from 45 to 63%, especially from 50 to 63%, by weight of the conductive material, particularly carbon. We prefer that the average diameter of the conductive material, e.g. carbon or graphite powder particles, should be from 40 to 150 μm.

A second crucial component of the composition of the present invention is a binder. Sufficient binder should be present to hold the conductive material together, while allowing it to flex, for example, as the body moves. Examples of suitable binders include: gum arabic, guar gum, xanthan gum, hypromellose, agar, an alginate (e.g. metal alginate, such as sodium alginate), carageenan, methylcellulose, hydroxymethyl cellulose, pectin, acacia, or gum tragacanth. The amount of binder (dry weight) is preferably from 3% to 7% by weight of the wet weight of the composition, more preferably from 4 to 6%, and most preferably from 4.01% to 5.18%.

The binder will normally be used as a solution in water, and the water in the binder will normally be the only water needed in the composition. In general, the water content of the composition will be from 10% to 42.98% by weight. More preferably the composition contains at least 30% by wet weight of the binder solution, still more preferably from 30% to 50%. Most preferably the composition contains from 33%-50%, especially 36%-49% by wet weight of the binder solution.

The third essential component of the composition of the present invention is a humectant. A humectant is a hygroscopic substance, which may be added to another substance to keep it moist. It is distinguished from the wetting agents used in, for example, CN 101240133, which are surface active agents, designed to reduce surface tension, and thus aid the admixture of otherwise incompatible materials. Examples of humectants that may be used in the present invention include glycerol, glycerin, propylene glycol, sorbitol, mannitol and glycerin triacetate, of which glycerol is preferred. The amount of humectant is preferably from 0.05 to 2% by weight, more preferably from 0.1 to 1.5% by weight, and most preferably from 0.15 to 1.3% by weight, based on the wet weight of the composition.

Other components may be added, if desired, to achieve specific results or mixture properties, as is well known to those skilled in the art. Examples of such additional components include: plasticizers, such as acetyl tributyl citrate, tributyl citrate, acetyl trioctyl citrate, trioctyl citrate, acetyl trihexyl citrate, trihexyl citrate, butyryl trihexyl citrate, or trimethyl citrate, preferably in an amount of from 1% to 20% by weight; and emulsifiers, such as lecithin, carboxymethyl cellulose, polyglycerol polyricinoleate, calcium stearoyl lactate, sodium stearoyl lactate, sodium carboxymethyl cellulose, preferably in an amount of from 1% to 20% by weight.

The composition of the present invention is preferably such that at least 90% of it will evaporate from a layer less than 1 mm in thickness, at the body temperature of 37.0° C., within 10 minutes at STP.

The binder, e.g. gum arabic, and the humectant, e.g. glycerin, are preferably heated together to the point at which they foam and collapse and then are allowed to cool. Once cool, the conductive powder, preferably carbon, is added and the mixture is ready to be applied to the skin (or other surfaces) as a conductive ink.

The composition of the present invention may be applied to the human or animal body (or, if desired, to another substrate) by any conventional means. For example, it may be applied using brushing, spraying or printing methods. It dries quickly on the skin, generally within 10 minutes. It then maintains its current-carrying ability whilst adhered to the skin, during body movement. The skin-safe conductive ink is preferably not permanent and may be removed from the skin by washing the skin with water. After the ink has dried, the carbon powder may be separated out by dissolving in water and reclaiming the particles. The ink may be used to form various types of electrical circuit, of which, in a preferred embodiment, the human or animal body forms part.

The functionality of a keyboard, for example, may be mapped onto a living body by forming resistance switches on skin that input signals to a computer or microchip. Wires are used to extend from keyboard input switches onto human skin, for example the palm of the hand. The wires interface with the skin via adhesive backed conductive fabric patches, adhered to the skin. The keyboard is connected to and relays signals to a computer. The skin-safe conductive ink of the present invention may be applied to the skin with a brush or other drawing implement and the switch is extended from the fabric patches to desired locations. This is repeated for the required number of inputs, such that a circuit diagram is built up on the palm of hand or other part of the skin. Resistance switches are operated by the flexing of particular digits or other dynamic interactions. An example is a switch that is bridged by touching an ink terminal on the forefinger to an ink terminal on the palm of the hand. This allows the user to create a variety of interactions via a computer. Some examples include dialling a telephone number or playing MIDI (Musical Instrument Digital Interface) notes by closing circuits on the body or between more than one body or between the body and an external object.

The invention is further illustrated by the following non-limiting Examples.

### EXAMPLE 1

### Material Composition

47.2 1 pts Gum Arabic (Winsor & Newton, Whitefriars Avenue Harrow Middlesex HA3 5RH England), and 1.13 pts Glycerin (Food Grade, Boots UK, PO Box 5300, Nottingham NG90 1AA) were combined and stirred until a uniform mixture was created. The mixture was then heated to 100° C. on a stovetop and stirred until the mixture began to foam. After approximately 3 minutes, while stirring continuously at 100° C., the foam collapsed. Once the foam had collapsed, the mixture was removed from heat. The mixture was then allowed to cool to room temperature (approximately 21° C.). Once cooled, 51.66 pts Activated Carbon Powder (Toho Tenax, Tenax-A Type 385, Toho Tenax Europe GmbH Kasinostr. 19-21, 42103 Wuppertal/Deutschland) wee added and stirred until mixture was uniform.

### Change In Electrical Resistance In Order To Infer Body Position

1. The aim of this application is to infer the relative position of a body part through a change in electrical resistance. The ink was painted onto an area of the body which stretched through movement (such as the outer elbow) and a range of electrical resistance values were read. Based upon these values the position of the body part can be inferred.

2. The uniform ink mixture was applied to the skin using a paintbrush either freehand or through a stencil onto an area of skin that stretches significantly during movement such as the elbow, wrist, fingers, knees, face, or neck. The ink was applied over the areas whose movement is to be detected (the affected area) at a depth of approximately 1 mm. Since this application depends on relative values, the shape and amount of ink used is unimportant as long as the ink covers the affected area in a continuous patch. The ink was allowed to dry.

3. Two separate wires were attached to the area of ink. These wires should make separate contact with the ink at the maximum available distance on the applied area of ink (they need to be as far away from each other as possible).

4. Without moving the affected area from the rest position, the electrical resistance between the two wires was measured either using a resistometry-enabled computer, or another device capable of measuring electrical resistance. The painted person is then asked to move the affected area throughout its range of motion until the skin had reached its point of maximum flexion. The electrical resistance was measured again. These two measurements of resistance establish a range of values that will be generated throughout the movement of the affected area.

5. The position of the body can then be inferred through locating the resistance values between the maximum and minimum resistance values established above. A dynamic reading of the position of the body is possible by watching the resistance values change over time.

6. This data can then be used to read a person's body position to detect a proper range of movement in an exercise routine or to control an analogue input in a computer, such as the pitch of a musical sample during a dramatic performance.

### Using the Body To Send Electrical Signals

1. The aim of this application is to paint a person with ink in such a way that their entire body becomes a “wire” allowing them to close a circuit just by touching two painted parts of their body between two electrodes. The ink must form a continuous strip between the parts of the body used to make contact between the two electrodes. This effect can be used to allow a person to control and trigger electrical events such as sounds and lighting.

2. The uniform ink mixture was applied to the skin using a paintbrush either freehand or through a stencil. The ink was applied in a continuous area from foot to hand, covering the feet, the legs, torso and arms. The ink was allowed to dry.

3. The ink was then used to close a circuit between two electrodes, enabling the entire body to act as a single “wire.” This circuit may be closed by touching two ends of a continuous area of ink to two different electrodes connected to a computer, emitting a low voltage signal (less than 9V DC). With a continuous area of ink connecting both of their feet and hands, this person could then close a circuit between two electrodes in three basic ways. By touching one hand to each electrode, one foot and one hand to each electrode or both feet.

4. Any area of contact can be used to create a circuit between the electrodes as long as a continuous area of ink exists on the body between the two points making contact with the electrodes. The person becomes a “switch” opening the channel for an electrical signal.

5. This application can be used to allow a person to control electrical signals such as during a dramatic performance, allowing one person to trigger many electrical events (lights, sounds) just by moving their body and touching parts of built environment. This application can also work with multiple persons so that they can close circuits using two bodies as one single “wire.”

### EXAMPLE 2

### Material Composition

37.3 pts Gum Arabic (Winsor & Newton, Whitefriars Avenue Harrow Middlesex HA3 5RH England), and 1.13 pts Glycerin (Food Grade, Boots UK, PO Box 5300, Nottingham NG90 1AA), were combined and stirred until a uniform mixture was created. The mixture was then heated to a temperature around 100° C. and stirred until the mixture began to foam. After approximately 3 minutes, while stirring continuously at 100° C., the foam collapsed and the mixture was removed from heat. The mixture was then allowed to cool at room temperature 21 ° C. Once cooled, 61.56 pts Activated Carbon Powder (Toho Tenax, Tenax-A Type 385, Toho Tenax Europe GmbH Kasinostr. 19-21, 42103 Wuppertal/Deutschland) were added and stirred until it was fully incorporated.

### Creating A Circuit To Light A Light Emitting Diode (LED)

1. The aim of this application is to create a circuit on the surface of the skin using ink. In this example, the circuit is used to light an LED by connecting between a small power source and the LED.

2. The uniform ink mixture was applied to the skin using a paintbrush either freehand or through a stencil. The ink was applied so that there were two distinct areas of ink that were not touching but were close enough together so that the wires from the power source and LED can reach the areas of ink. The ink was allowed to dry.

3. The positive electrode (anode) of a small power source (four 1.5 V DC batteries, total of 6 V DC) was connected to one area of ink, while the negative electrode (cathode) of the power source was connected to the second area of ink.

4. The anode of the LED was then connected to the same area of ink that the anode of the power source was connected to. The cathode of the LED was then connected to the same area of ink that the cathode of the power source is connected to, thus creating a circuit between the LED and the power source. The power source and LED can either be adhered to the skin with a skin safe adhesive (Osto-bond Skin Bonding Cement, Montreal Ostomy, Montreal, Quebec, Canada) or can be held on the skin by hand as a demonstration of the ink's conductivity.

### EXAMPLE 3

### Material Composition

38.25 pts Gum Arabic (Winsor & Newton, Whitefriars Avenue Harrow Middlesex HA3 5RH England), and 0.19 pts Glycerin (Food Grade, Boots UK, PO Box 5300, Nottingham NG90 1AA), were combined and stirred until a uniform mixture was created. The mixture was then heated to a temperature around 100° C. and stirred until the mixture began to foam. After approximately 3 minutes, while stirring continuously at 100° C., the foam collapsed and the mixture was removed from heat. The mixture was then allowed to cool at room temperature (approximately 21° C.). Once cooled, 61.56 pts Activated Carbon Powder ((Toho Tenax, Tenax-A Type 385, Toho Tenax Europe GmbH Kasinostr. 19-21, 42103 Wuppertal/Deutschland) were added and stirred until it was fully incorporated.

### Creating A Circuit To Light A Light Emitting Diode (LED)

1. The aim of this application is to demonstrate both the conductivity of the ink and the use of the ink on surfaces other than skin. This application uses ink to create a circuit between a LED and a power supply, on a piece of paper (300 GSM watercolour paper).

2. The uniform ink mixture was applied to the paper in order to create a simple circuit between an LED and a small power source (four 1.5 V DC batteries, total of 6 V DC) using either a paintbrush or a stencil.

3. The circuit was designed so that there were two separate areas of ink connecting the anode of the power source to the anode of the LED and the cathode of the power source to the cathode of the LED. A stencil was cut from a material such as adhesive-backed vinyl so that the stencil can be temporarily adhered to the paper. The ink was then painted over the stencil and allowed to dry. Once dry, the stencil was removed, leaving the circuit formed in ink.

4. The LED and the power supply were then connected to the ends of the circuit using wires, lighting the LED.

### Creating A Circuit To Act As Potential Divider (Potentiometer)

1. The aim of this application is to demonstrate the ink as a potential divider. Specifically this application will use this property to change the brightness of a LED by allowing a user to manipulate a voltage drop between a power supply and a LED.

2. The circuit required by this application was painted in ink and can be painted either freehand or by stencilling. A circuit was designed so that the electrical resistance of one portion of the circuit remained constant where another portion of the circuit had variable electrical resistance. For example the anode of an LED was connected to the anode of a small power supply (four 1.5 V DC batteries, total of 6 V DC) through a continuous line of ink (5 mm wide, 150 mm long and lmm deep) with constant resistance.

3. The second part of the circuit required two lines of ink, each attached separately to the cathode of the power supply and the cathode of the LED. The cathode of the LED and the cathode of the power supply were attached via wires, to the ends of two separate parallel lines of ink (5 mm wide, 150 mm long, 1 mm deep, and 3 mm spacing in between). The effect of this was to extend both cathodes, with sufficient length to allow for a change in resistance across their length.

4. Once the ink was dry, a fourth, small section of ink was painted on either a separate substrate or on a person's finger. This fourth area of ink needed to be large enough to bridge the gap between the two parallel lines of ink attached to the battery and LED (in this example, larger than the 3 mm spacing between the parallel lines, so 5 mm wide, 5 mm long and 1 mm deep would be sufficient).

5. This fourth area of ink was then used to connect between the two parallel lines. If the connection is made between the two lines of ink at the end furthest from the cathode's attachment points then the resistance of the circuit will be greater than the resistance established by making a connection between the lines of ink at the closest point to the cathode's attachment points. The fourth area of ink was effectively used to change the circuitry distance (total amount of ink which the electrical charge will flow through) between the LED cathode and the battery cathode. The resistance in the circuit can be varied dynamically by bridging and sliding the fourth area of ink along the length of the two parallel lines of ink.

6. The change in resistance of the circuit as the fourth area of ink is placed on different parts of the parallel ink lines creates a change in the brightness of the LED. This effect could be used to control other analogue devices as well, or, through an analogue-digital interface, the sound volume in a computer that is playing music.

### Creating A Coil To Act As A Passive Radio Frequency Identification Device (RFID)

1. Passive radio frequency identification devices (RFIDs) are increasingly used as means to mark objects, enabling identification, tracking, or authentication of articles. RFID tags can be placed on goods, fabric, livestock, packaging, or any item where it may be necessary to identify, track, or authenticate objects (as per, The art of UHF RFID antenna design: impedance matching and size-reduction techniques, Published in IEEE Antennas and Propagation Magazine, Vo. 50, N. 1, Jan. 2008). In this application, the aim is to create a passive RFID tag on the body. The RFID tag consists of a coil and a chip whose memory contains the unique number of the specific tag. The coil is created from conductive ink and the chip is a standard industry part. When subjected to the electromagnetic field produced by an RFID reader, a current is induced in the coil, causing the chip to transmit its unique identification number, which is read by the reader.

2. To create the coil, the uniform ink mixture is applied to the skin using a stencil. The ink is applied in the form of an antenna coil so that a continuous line of ink coils around itself without touching. A chip containing the unique identification number is adhered to the inner section of the coil through the ink, or with a skin safe adhesive (Osto-bond Skin Bonding Cement, Montreal Ostomy, Montreal, Quebec, Canada). The ink is allowed to dry.

3. When placed in the electromagnetic field produced by the RFID reader, the RFID tag broadcasts its unique identification number, allowing for the specific identification of individual tags.

### EXAMPLE 4

### Material Composition

47.2 1 pts Gum Arabic (Winsor & Newton, Whitefriars Avenue Harrow Middlesex HA3 5RH England), and 1.13 pts Glycerin (Food Grade, Boots UK, PO Box 5300, Nottingham NG90 1AA) were combined and stirred until a uniform mixture was created. The mixture was then heated to 100° C. on a stovetop and stirred until the mixture began to foam. After approximately 3 minutes, while stirring continuously at 100° C., the foam collapsed. Once the foam had collapsed, the mixture was removed from heat. The mixture was then allowed to cool to room temperature (approximately 21° C.). Once cooled, 51.66 pts Activated Carbon Powder (Toho Tenax, Tenax-A Type 385, Toho Tenax Europe GmbH Kasinostr. 19-21, 42103 Wuppertal/Deutschland) wee added and stirred until mixture was uniform.

### Application of Ink To the Skin In Order To Adhere Electrode

1. The aim of this application is to use conductive ink as both an adhesive and a conductive membrane for the attachment of medical electrodes. This example could apply to medical electrodes which read ionic currents from the body, stimulate tissue through voltage, or any other electrode that reads or sends electrical signals through the skin.

2. The uniform ink mixture is applied to the skin in a shape mimicking the shape of the electrode to be adhered, using a stencil or a brush.

3. The Electrode is placed on top of the ink and is held temporarily in place (by medical tape, or another means of temporary location of the electrode) until the ink has dried. Once the ink is dry, the ink will remain conductive and will adhere the electrode to the skin for up to 10 hours.

4. Once the electrode is successfully adhered to the skin it is then connected to whatever monitoring device that is to be used.

### EXAMPLE 5

### Material Composition

41.36 pts Gum Arabic (Winsor & Newton, Whitefriars Avenue Harrow Middlesex HA3 5RH England), and 0.19 pts Glycerin (Food Grade, Boots UK, PO Box 5300, Nottingham NG90 1AA) were combined and stirred until a uniform mixture was created. The mixture was then heated to 100° C. on a stovetop and stirred until the mixture began to foam. After approximately 3 minutes, while stirring continuously at 100° C., the foam collapsed. Once the foam had collapsed, the mixture was removed from heat. The mixture was then allowed to cool to room temperature (approximately 21° C.). Once cooled, 51.66 pts Activated Carbon Powder (Toho Tenax, Tenax-A Type 385, Toho Tenax Europe GmbH Kasinostr. 19-21, 42103 Wuppertal/Deutschland) wee added and stirred until mixture was uniform.

### Application of Ink To the Skin In Order To Infer Perspiration

1. The aim of this application is to use conductive ink as a sensor that will infer change in skin perspiration through a change in electrical resistance (as per United States Patent: 7383072, “Sweat sensor system and method of characterizing the compositional analysis of sweat fluid”). The electrical prosperities of the ink change predictably when the ink makes contact with water. Thereby allowing the correlation between change in electrical resistance and change in perspiration.

2. The uniform ink mixture is applied to the skin using a stencil in the area that is to be measured.

3. Once the ink has dried, two wires are attached to the ink surface at the furthest possible point from each other, maximizing the ink area between the attachments of the wires. The wires can be attached using a skin safe adhesive (Osto-bond Skin Bonding Cement, Montreal Ostomy, Montreal, Quebec, Canada) or a medical tape (Blenderm Surgical Tape, 3M, Minnesota, USA).

4. The resistance between the wires is then measured to establish a base reading, which can be correlated with other bio descriptors such as heart rate. During the observation process the change in electrical resistance of the ink can be read and used to monitor the perspiration of the skin.

1. An ink suitable for application to the human or animal body, wherein the ink comprises a particulate conductive material, a binder and a humectant, wherein the conductive material is present in sufficient amount that the ink, once dry, is electrically conductive.

2. The ink according to claim 1, wherein the conductive material is in powder or flake form.

3. The ink according to claim 1, wherein the conductive material is an electrically conductive metal.

4. The ink according to claim 1, wherein the conductive material is an electrically conductive non-metal.

5. The ink according to claim 19, wherein the carbon is in the form of graphite, carbon black, activated carbon powder, powdered activated carbon, carbon nanotubes, or powdered charcoal.

6. The ink according to claim 1, wherein the ink comprises at least 30% by weight of the conductive material, based on the wet weight of the ink.

7. The ink according to claim 6, wherein the ink contains at least 35% by weight of the conductive material.

8. The ink according to claim 6, wherein the ink contains from 45 to 63% by weight of the conductive material.

9. The ink according to claim 1, wherein the average diameter of the conductive material is from 40 to 150 μm.

10. The ink according to claim 1, wherein the binder is gum arabic, guar gum, xanthan gum, hypromellose, agar, an alginate, carageenan, methylcellulose, hydroxymethyl cellulose, pectin, acacia, or gum tragacanth.

11. The ink according to claim 1, wherein the amount of binder (dry weight) is from 3% to 7% by weight of the wet weight of the ink.

12. The ink according to claim 1, wherein the ink contains water in an amount of from 10% to 42.98% by weight.

13. The ink according to claim 1, wherein the humectant is glycerol, glycerin, propylene glycol, sorbitol, mannitol, or glycerin triacetate.

14. The ink according to claim 13, wherein the humectant is glycerol.

15. The ink according to claim 1, wherein the amount of humectant is from 0.05 to 2% by weight based on the wet weight of the ink.

16. An electrical circuit, wherein the electrical circuit comprises an electrical power source, and a device utilising electrical power, wherein the electrical power source and the device are connected by an electrically conductive material, wherein the electrically conductive material comprises an ink suitable for application to the human or animal body, and wherein the ink comprises a particulate conductive material, a binder, and a humectant.

17. (canceled)

18. The ink according to claim 3, wherein the electrically conductive metal is silver, gold, or copper.

19. The ink according to 4, wherein the electrically conductive non-metal is carbon.

20. The ink according to claim 7, wherein the ink contains from 35 to 70% by weight of the conductive material.

21. The ink according to claim 6, wherein the ink contains from 50 to 63% a by weight of the conductive material.

22. The ink according to claim 1, wherein the amount of binder (dry weight) is from 4% to 6% by weight of the wet weight of the ink.

23. The ink according to claim 1, wherein the amount of humectant is from 0.1 to 1.5% by weight based on the wet weight of the ink.

24. The ink according to claim 10, wherein the alginate is sodium alginate.
